(19) United States
(12) Patent Application Publication
(10) Pub. No.: US 2015/0092349 A1
(43) Pub. Date: Apr. 2, 2015

(54) IMPLEMENTING REDUNDANT AND HIGH EFFICIENCY HYBRID LIQUID AND AIR COOLING FOR CHIPSTACKS

(71) Applicant: International Business Machines Corporation, Armonk, NY (US)

(72) Inventors: Bret P. Elison, Rochester, MN (US); Phillip V. Mann, Rochester, MN (US); Arden L. Moore, Cedar Park, TX (US); Arvind K. Sinha, Rochester, MN (US)

(73) Assignee: International Business Machines Corporation, Armonk, NY (US)

(21) Appl. No.: 14/042,875

(22) Filed: Oct. 1, 2013

(51) Int. Cl. H05K 7/20

(52) U.S. Cl. CPC H05K 7/20218; H05K 7/20127
USPC 361/698

(57) ABSTRACT

A method and apparatus are provided for implementing redundant and high efficiency hybrid liquid and air cooling for chipstacks. The apparatus includes an electronic module having a chipstack of one or more semiconductor chips; a liquid heat sink lid over the chipstack; an inlet flow and an outlet flow enabling a low viscosity dielectric liquid to pass through the lid and around the chipstack of the electronic module; a top of said electronic module providing an airflow heat sink support surface for airflow cooling used in parallel to under-lid liquid cooling.

### FIELD OF THE INVENTION

The present invention relates generally to the data processing field, and more particularly, relates to method and apparatus for implementing redundant and high efficiency hybrid liquid and air cooling for chipstacks.

### DESCRIPTION OF THE RELATED ART

Three dimensional (3D) integrated architectures have been heralded as the next major progression in chip technology. By stacking processing cores, memory, and other functional areas vertically within the chip stack the signal path lengths are greatly reduced and significant performance gains over current planar chip architectures are possible.

However, this type of vertical integration also creates a very challenging set of conditions that traditional thermal management packaging techniques are ill-equipped to meet. Due to the stacking of multiple functional groups, the power density within the chip structure can be very high and improved horizontal heat spreading capabilities are required to ensure the chip assembly is not susceptible to localized hot spots.

In addition, the 3D architecture is necessarily thicker and comprised of many more layers and interfaces that lie perpendicular to the primary vertical path of conduction relied on in most current package design. The increased thickness and interface density act as additional thermal conduction resistances and impede efficient cooling of the chip. Thus, current packaging approaches are not well suited to meet the specific demands of 3D chip architectures.

Several novel arrangements have been proposed previously for cooling 3D chip stacks, including impinging jets and interior microchannels. However, these methods often provide little or no redundancy in order to protect the chip in the event of a thermal management apparatus failure or shutdown. Thus, the server or computer in question may have a very elaborate and expensive cooling approach that also represents a single point of failure which can bring the system down. This lack of redundancy is viewed as unacceptable in almost all areas of modern server technology.

A need exists for an efficient and effective method and apparatus for implementing enhanced and redundant cooling for chipstacks.

### SUMMARY OF THE INVENTION

Principal aspects of the present invention are to provide a method and apparatus for implementing redundant and high efficiency hybrid liquid and air cooling for chipstacks or an electronic module having one or more semiconductor chips. Other important aspects of the present invention are to provide such method and apparatus substantially without negative effects and that overcome many of the disadvantages of prior art arrangements.

In brief, a method and apparatus are provided for implementing redundant and high efficiency hybrid liquid and air cooling for chipstacks. The apparatus includes an electronic module having a chipstack of one or more semiconductor chips; a liquid heat sink lid over the chipstack; an inlet flow and an outlet flow enabling a low viscosity dielectric liquid to pass through the lid and around the chipstack of the electronic module; a top of said electronic module providing an airflow heat sink support surface for airflow cooling used in parallel to under-lid liquid cooling.

In accordance with features of the invention, the liquid cooling and the airflow cooling provide parallel functionality that is not normally obtainable in cooling processes due to the typical conduction path used in classical cooling methods.

In accordance with features of the invention, both the liquid cooling and the airflow cooling methods function independently of each other and take over cooling needs in the event one of them fails.

In accordance with features of the invention, while having an air-cooled component, the liquid cooling aspect and associated hot spot mitigation allows the system to run at much lower fan speeds and airflow rates than an air-only architecture, thereby reducing system noise and data center-level airflow demands as well.

In accordance with features of the invention, the liquid heat sink lid includes extruded fins extending downwardly and generally surrounding the chipstack.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1, 2, and 3 are perspective views not to scale schematically illustrating example apparatus for implementing redundant and high efficiency hybrid liquid and air cooling for three dimensional (3D) chipstacks in accordance with the preferred embodiment;

FIGS. 4 and 5 are respective graphs illustrating example respective operation of prior art air cooling apparatus and the apparatus for implementing redundant and high efficiency hybrid liquid and air cooling for chipstacks of FIG. 1 in accordance with the preferred embodiment;

FIGS. 6 and 7 are respective top down and side views not to scale schematically illustrating example prior art heat chipstack temperature density; and

FIGS. 8 and 9 are respective side and top down views not to scale schematically illustrating example heat chipstack temperature density for the apparatus for implementing redundant and high efficiency hybrid liquid and air cooling for chipstacks of FIG. 1 in accordance with the preferred embodiment.

### DETAILED DESCRIPTION OF THE PREFERRED EMBODIMENTS

In the following detailed description of embodiments of the invention, reference is made to the accompanying drawings, which illustrate example embodiments by which the invention may be practiced. It is to be understood that other embodiments may be utilized and structural changes may be made without departing from the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In accordance with features of the invention, a method and apparatus are provided for implementing redundant and high efficiency hybrid liquid and air cooling for chipstacks.

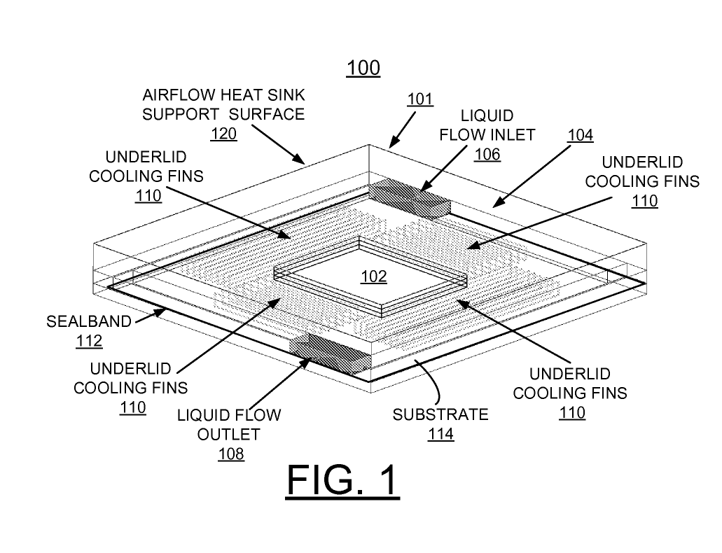

Referring now to FIGS. 1, 2, and 3, there are shown perspective views not to scale schematically illustrating example apparatus generally designated by the reference character 100 for implementing redundant and high efficiency hybrid liquid and air cooling for three dimensional (3D) chipstacks in accordance with the preferred embodiment.

In FIGS. 1, 2, and 3, apparatus 100 includes an electronic module 101 having a chipstack 102 of one or more semiconductor chips. Apparatus 100 includes a liquid heat sink lid 104 over the chipstack 102. The liquid heat sink lid 104 includes a liquid flow inlet 106 and a liquid flow outlet 108 enabling a low viscosity dielectric liquid to pass through the liquid heat sink lid 104 and around the chipstack 102 in the electronic module 101. The liquid heat sink lid 104 includes a plurality of underlid cooling fins 110 extending downwardly and generally surrounding the chipstack 102. The multiple underlid cooling fins 110 are, for example, extruded fins integrally formed with the liquid heat sink lid 104.

In FIG. 1, a sealband 112 extending around the electronic module 101 and carried by a substrate 114 of the electronic module 101 provides a fluid tight seal. A top airflow heat sink supporting surface 120 of electronic module 101 supports an airflow heat sink for airflow cooling advantageously used in parallel to under-lid liquid cooling. Various configurations can be provided for the airflow heat sink carried on the top surface 120 of the electronic module 101.

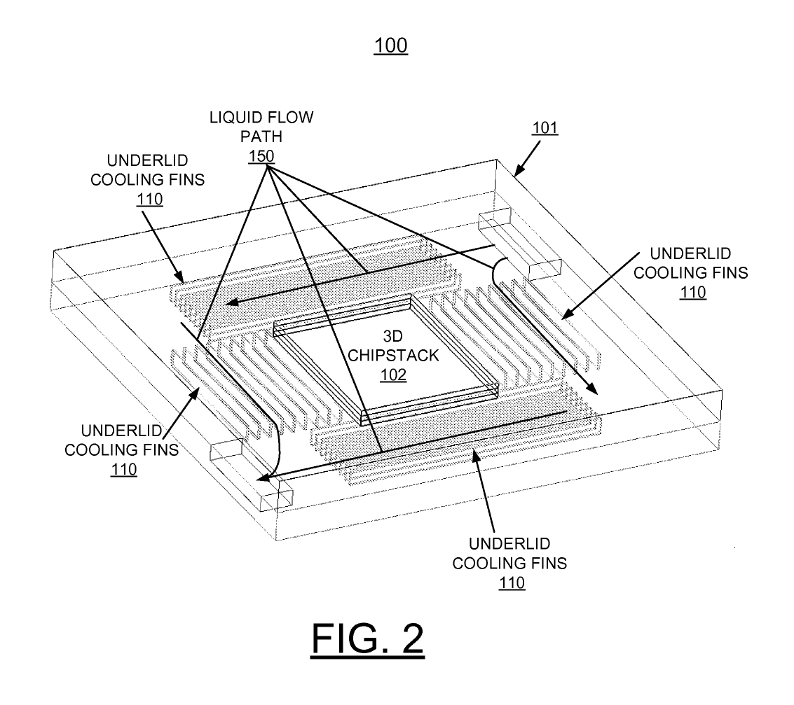

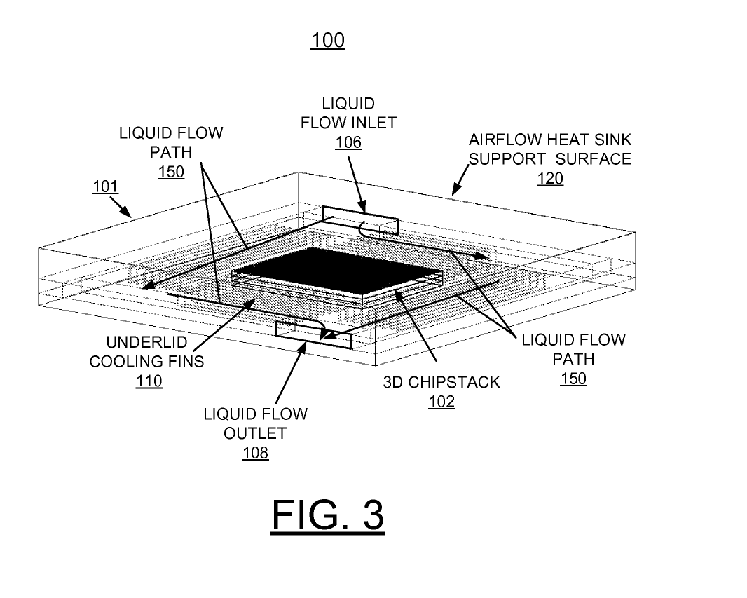

As shown in FIGS. 2 and 3, a liquid flow path generally designated by the reference character 150 of apparatus 100 is shown relative multiple underlid cooling fins 110. A low viscosity dielectric cooling liquid passes through liquid flow inlet 106 and liquid flow outlet 108 and through the underlid cooling fins 110 of the liquid heat sink lid 104 and around the chipstack 102 in the electronic module 101.

The liquid heat sink lid 104 is formed of a highly thermally conductive material, such as aluminum or copper. The low viscosity dielectric cooling liquid flows between adjacent underlid cooling fins 110 within the liquid flow path 150 surrounding the chipstack 102.

In accordance with features of the invention, the hybrid liquid and air cooling methods advantageously are independent of each other and take over cooling needs in the event one of them fails. Despite having an air-cooled component, the liquid cooling aspect and associated hot spot mitigation allow the system to run at much lower fan speeds and airflow rates than an air-only architecture, thereby reducing system noise and data center-level airflow demands as well.

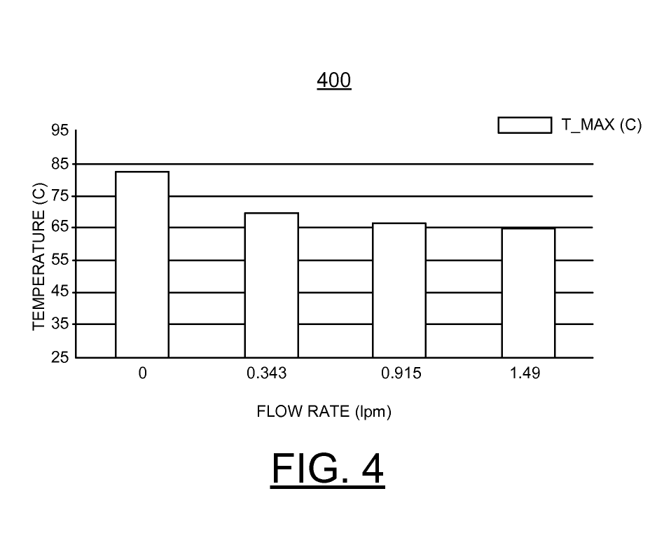

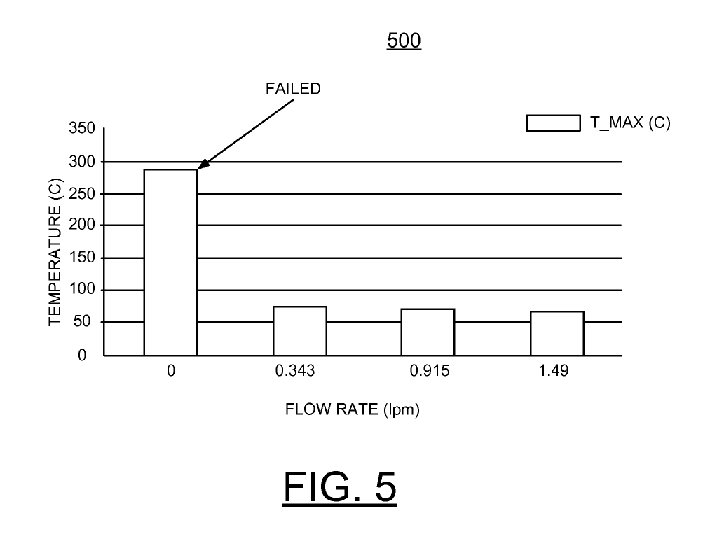

Referring also to FIGS. 4 and 5, there are shown respective graphs illustrating example respective operation of prior art air cooling apparatus and apparatus 100 for implementing redundant and high efficiency hybrid liquid and air cooling for chipstacks 102 in accordance with the preferred embodiment.

In FIG. 4, the operation generally designated by the reference character 400 of prior art air cooling apparatus shown relative to operation of apparatus 100 with temperature shown relative the vertical axis and flow rate shown relative the horizontal axis. In FIG. 5, the operation generally designated by the reference character 500 of operation of apparatus 100 with a maximum temperature T_Max under heat sink or airflow failure.

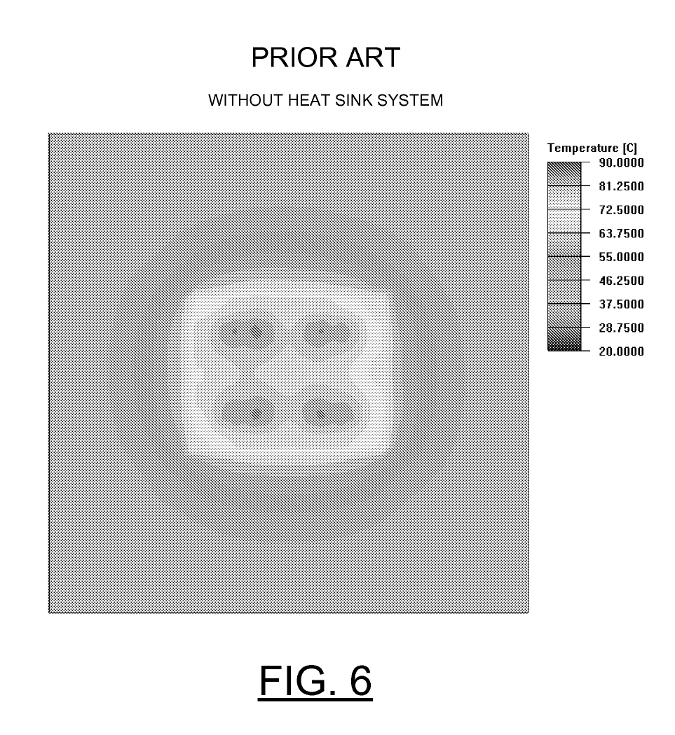

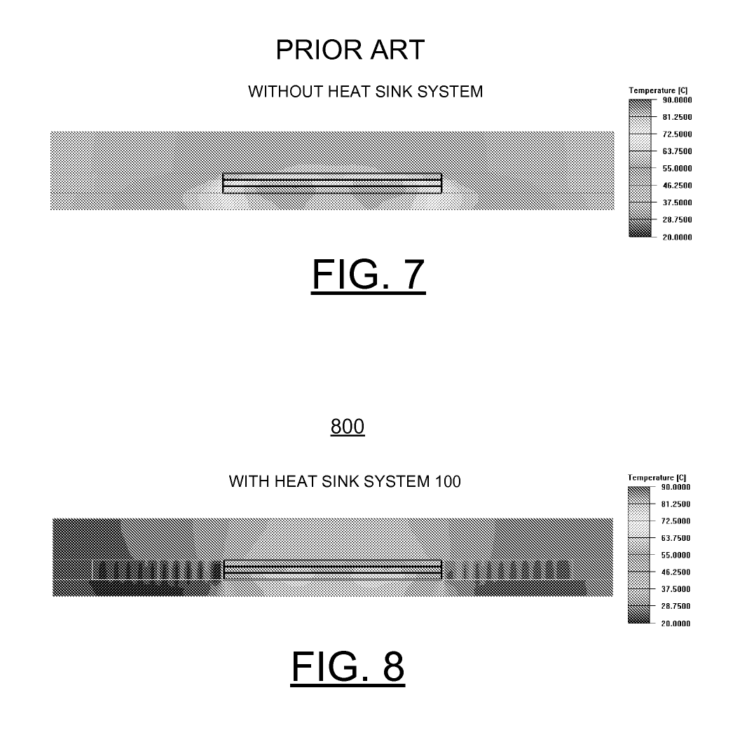

FIGS. 6 and 7 are respective top down and side views illustrating example prior art chipstack temperature density without a heat sink system.

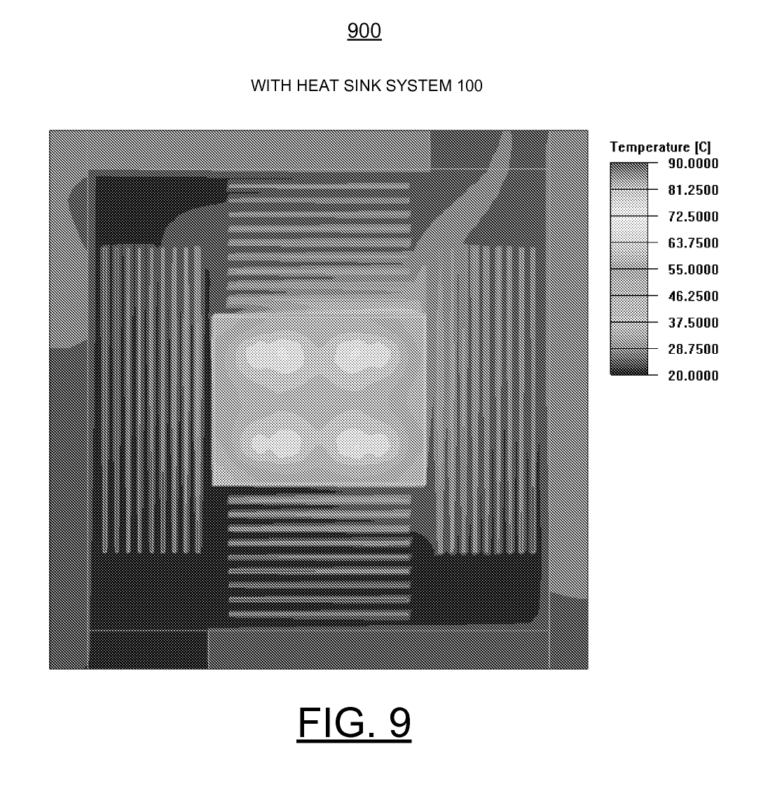

Referring also to FIGS. 8 and 9, there are shown respective example side and top down view example heat chipstack temperature density generally designated by the reference character 800, 900 for the apparatus 100 in accordance with the preferred embodiment. As can be seen by comparing hybrid liquid and air cooling temperature density 800, 900, with the prior art chipstack temperature density without a heat sink system, the present invention combines the effectiveness of liquid cooling and the reliability of air cooling to provide efficient, redundant removal of heat from a 3D chip stack 102.

While the present invention has been described with reference to the details of the embodiments of the invention shown in the drawing, these details are not intended to limit the scope of the invention as claimed in the appended claims.

What is claimed is:

1. An apparatus for implementing redundant and high efficiency hybrid liquid and air cooling for chipstacks comprising:
an electronic module having a chipstack of one or more semiconductor chips;
said electronic module having a liquid heat sink lid extending over the chipstack;
said liquid heat sink lid having a liquid flow inlet and a liquid flow outlet enabling a low viscosity dielectric liquid to pass through said liquid heat sink lid and around the chipstack for under-lid liquid cooling; and
a top of said electronic module providing an airflow heat sink support surface for airflow cooling used in parallel to underlid liquid cooling.

2. The apparatus as recited in claim 1 wherein said liquid heat sink lid includes a plurality of fins extending downwardly and generally surrounding the chipstack.

3. The apparatus as recited in claim 2 wherein said plurality of fins include extruded fins integrally formed with said liquid heat sink lid.

4. The apparatus as recited in claim 2 includes thermally conductive downwardly extending fins.

5. The apparatus as recited in claim 1 wherein the underlid liquid cooling and airflow cooling function independently of each other.

6. The apparatus as recited in claim 1 includes a sealband extending around said electronic module and carried by a substrate of the electronic module, said sealband providing a fluid tight seal.

7. The apparatus as recited in claim 1 includes said liquid heat sink lid having a plurality of integrally formed downwardly extending underlid cooling fins, said underlid cooling fins generally surrounding the chipstack of the electronic module.

8. The apparatus as recited in claim 7 wherein said underlid cooling fins include a liquid flow path around the chipstack of the electronic module.

9. A method for implementing redundant and high efficiency hybrid liquid and air cooling for chipstacks comprising:
providing an electronic module having a chipstack of one or more semiconductor chips;
providing said electronic module having a liquid heat sink lid extending over the chipstack;
providing said liquid heat sink lid having a liquid flow inlet and a liquid flow outlet enabling a low viscosity dielectric liquid to pass through said liquid heat sink lid and around the chipstack of the electronic module; and
providing an airflow heat sink support surface for airflow cooling used in parallel to under-lid liquid cooling with a top of said electronic module.

10. The method as recited in claim 9 includes forming said liquid heat sink lid of a thermally conductive material.

11. The method as recited in claim 10 wherein said thermally conductive material includes aluminum and copper.

12. The method as recited in claim 9 includes providing a plurality of thermally conductive downwardly extending fins with said liquid heat sink lid generally surrounding the chipstack.

13. The method as recited in claim 12 includes integrally forming extruded fins with said liquid heat sink lid.

14. The method as recited in claim 12 includes providing a liquid flow path around the chipstack of the electronic module with said plurality of thermally conductive downwardly extending fins.

15. The method as recited in claim 9 includes providing a sealband extending around said electronic module and carried by a substrate of the electronic module, said sealband providing a fluid tight seal.

16. The method as recited in claim 9 includes providing the underlid liquid cooling and airflow cooling for functioning independently of each other.
